(19) United States
(12) Patent Application Publication
(10) Pub. No.: US 2009/0065859 A1
(43) Pub. Date: Mar. 12, 2009

(54) TRENCH TRANSISTOR AND METHOD FOR MANUFACTURING THE SAME

(76) Inventors: Byung-Tak Jang, Seongnam-si (KR); Yeo-Cho Yoon, Yeongdeungpo-gu (KR)

Correspondence Address: SHERR & VAUGHN, PLLC, 620 HERNDON PARKWAY, SUITE 200, HERNDON, VA, 20170, US

(21) Appl. No.: 12/197,274

(22) Filed: Aug. 24, 2008

(30) Foreign Application Priority Data
Sep. 7, 2007 (KR) 10-2007-0090948

(51) Int. Cl. H01L 29/78; H01L 21/336

(52) U.S. Cl. 257/330; 438/270; 257/E29.262; 257/E21.41

(57) ABSTRACT

A trench transistor and a manufacturing method for the same are disclosed. The manufacturing method includes preparing a semiconductor substrate, forming a trench in the semiconductor substrate, forming a gate oxide layer over an inner wall of the trench, forming a gate having a first conductivity type by embedding polysilicon in the trench, the gate including a protruding portion protruding over a surface of the semiconductor substrate, forming a barrier layer by implanting second conductivity type ions in the protruding portion, and forming a second conductivity type source region over the surface of the semiconductor substrate.

The present application claims priority under 35 U.S.C. 119 to Korean Patent Application No. 10-2007-0090948 (filed on Sep. 7, 2007), which is hereby incorporated by reference in its entirety.

### BACKGROUND

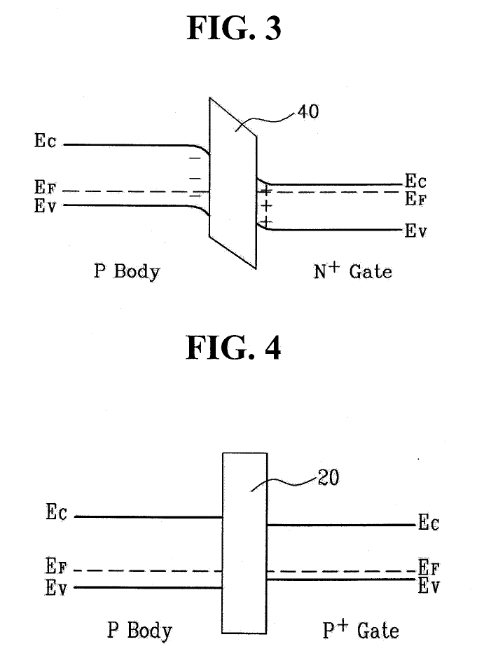

A conventional trench transistor is disclosed in U.S. Pat. No. 6,583,010B2 (entitled “Trench transistor with self-aligned source”). In the disclosed trench transistor, ion implantation is performed to reduce gate-source overlap capacitance as shown in FIG. 6A or FIG. 6C of the patent, thereby forming an L-shape source structure as shown in FIG. 6D of the patent.

According to this method, since the source is formed through self alignment with a terminal at an upper part of the gate, the overlap capacitance between the source and the gate can be reduced, while also reducing variation in the overlap capacitance. However, the above method is applicable only when a trench gate is formed lower than a silicon surface, that is, inapplicable when the trench gate is higher than the silicon surface.

When a gate electrode protrudes above the silicon surface, a source contact having a self aligning structure can be achieved by forming sidewalls in the same manner as in a general CMOS transistor process. When contacts of the body and the source are formed through the self alignment, the surface area of the device can be reduced. This is also helpful for guaranteeing a process margin. When the gate electrode protrudes higher than the silicon surface, the gate-source overlap capacitance is increased whereas resistance of the gate can be reduced.

### SUMMARY

Embodiments relate to a transistor such as a field effect transistor (FET) of a metal-oxide semiconductor (MOS), and more particularly, to a trench transistor having a gate in the form of a trench and a method for manufacturing the same. Embodiments relate to a trench transistor which is capable of reducing a gate-source overlap capacitance with a gate electrode protruding higher than a surface of a semiconductor substrate, and a method for manufacturing the same. Embodiments relate to a trench transistor with a relatively high threshold voltage despite using a relatively thin gate oxide layer, and a method for manufacturing the same.

Embodiments relate to a trench transistor which may include a semiconductor substrate, a trench formed within the semiconductor substrate, and a gate oxide layer formed over an inner wall of the trench. A gate may be embedded in the trench including a protruding portion partly protruding over a surface of the semiconductor substrate. The gate may be doped with second conductivity type dopants around the protruding portion, and with first conductivity type dopants on other portions excluding the protruding portion. A source region of a second conductivity type may be formed over the surface of the semiconductor substrate at lateral sides of the trench.

Embodiments relate to a method for manufacturing a trench transistor includes: preparing a semiconductor substrate; forming a trench in the semiconductor substrate; forming a gate oxide layer over an inner wall of the trench; forming a gate having a first conductivity type by embedding polysilicon in the trench, the gate including a protruding portion protruding over a surface of the semiconductor substrate; forming a barrier layer by implanting second conductivity type ions in the protruding portion; and forming a second conductivity type source region over the surface of the semiconductor substrate.

### DRAWINGS

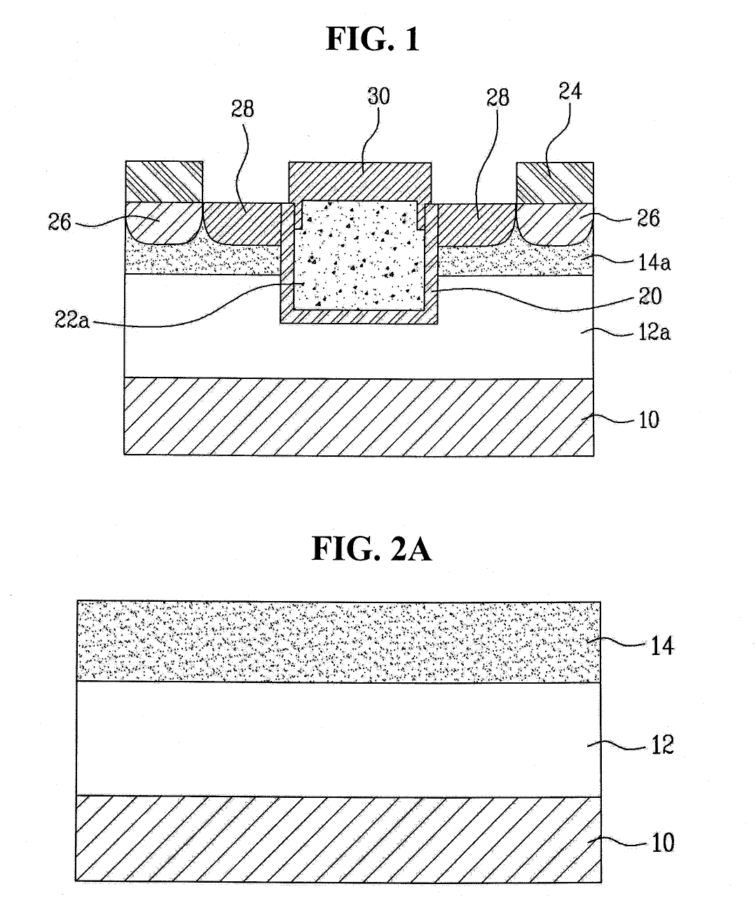

Example FIG. 1 is a sectional view of a trench transistor according to embodiments.

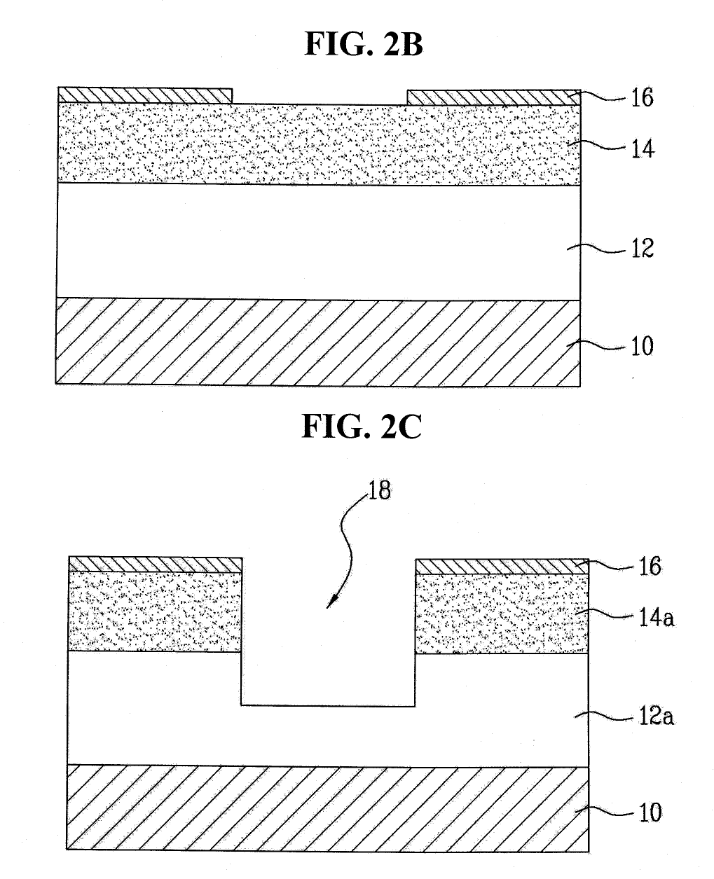

Example FIG. 2A through example FIG. 2G are sectional views showing the processes of forming the trench transistor according to embodiments.

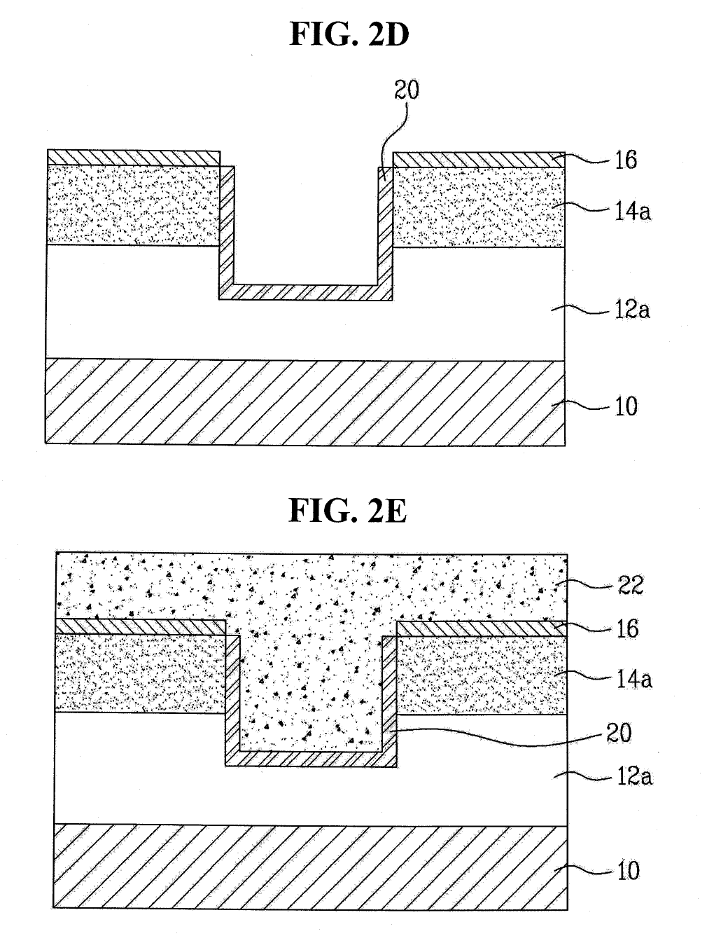

Example FIG. 3 is an energy band diagram showing a state where a body and a gate have different conductivity types from each other.

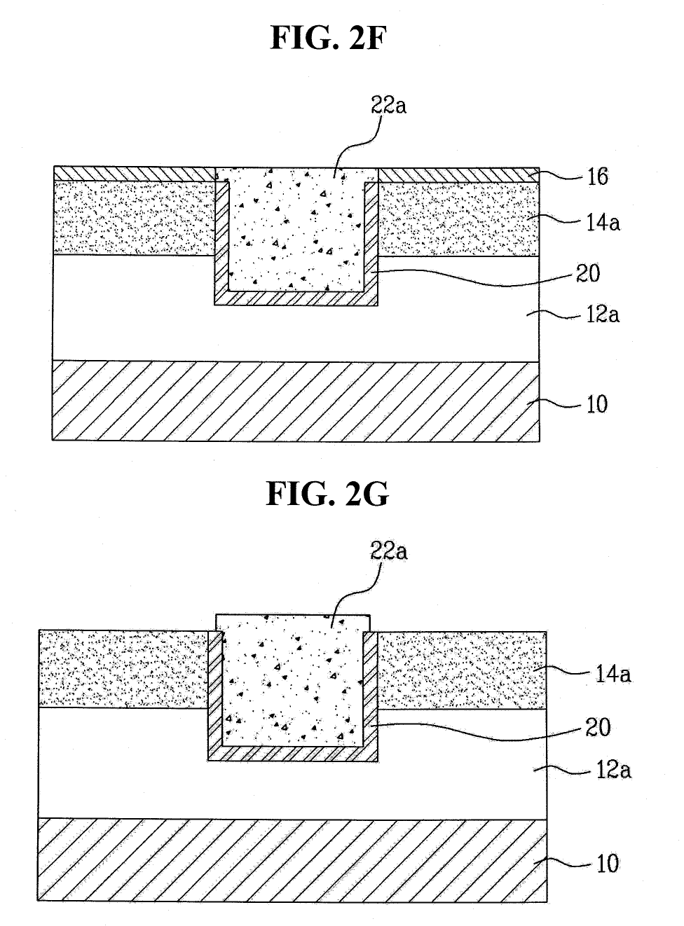

Example FIG. 4 is an energy band diagram showing a state where a body and a gate have the same conductivity type.

### DESCRIPTION

Example FIG. 1 is a sectional view of a trench transistor according to embodiments. Referring to example FIG. 1, the trench transistor may include a gate oxide layer 20 formed over an inner wall of a trench which is formed in a semiconductor substrate. More specifically, the structure includes the semiconductor substrate, a high-density second conductivity type drain region 10, a low-density second conductivity type drain region 12a and a first conductivity type body or well 14a. The trench may be formed over the low-density second conductivity type drain region 12a and the first conductivity type body 14a. The first conductivity type and the second conductivity type may be opposite. For example, when the first conductivity type is a P type, the second conductivity type is an N type, and vice versa.

According to embodiments, a gate 22a of the trench transistor protrudes over a surface of the semiconductor substrate, that is, a surface of the body 14a, filling the trench up to an upper part of the gate oxide layer 20. Herein, the gate 22a may be formed of polysilicon having the same conductivity type as the body 14a of the semiconductor substrate, which may be the first conductivity type.

As distinguished from transistors having a gate which has the same conductivity type as a drain region, which may be the second conductivity type, the gate 22a of embodiments according to example FIG. 1 has the first conductivity type whereas the drain region has the second conductivity type oppositely to the gate 22a. In addition, the gate 22a may include a barrier layer 30 formed over and around the protruding portion thereof. More specifically, the barrier 30 may be formed over an upper part and side parts of the protruding gate 22a.

Additionally, the trench transistor may use the second conductivity type, same as the barrier layer 30. A source region 28 may be formed over the surface of the body 14a at both sides of the trench. The source region 28 and the barrier layer 30 may be formed using a photosensitive film mask 24. In other words, in the trench transistor according to embodiments, the barrier layer 30 may be formed between the gate 22a and the source region 28. The trench transistor may include a high density first conductivity type body 26 over the surface of the body 14a.

Hereinafter, a method for manufacturing the trench transistor according to embodiments shown in example FIG. 1 will be explained with reference to the accompanying drawings. Example FIG. 2A through example FIG. 2G are sectional views for explaining processes of manufacturing the trench transistor. Referring to example FIG. 2A, the first conductivity type body 14a, the high-density second drain region 10 and the low-density second drain region 12a may be formed by ion implantation or epitaxy.

Referring to example FIG. 2B, a mask 16 which exposes a region for forming the trench and covers the other regions may be formed over an upper part of the first conductivity type body 14 by photolithography patterning. More particularly, the mask 16 may be formed by depositing a silicon oxide (SiO₂) layer over the upper surface of the first conductivity type body 14a by chemical vapor deposition (CVD) and patterning the deposited SiO₂ layer.

As shown in example FIG. 2C, the first conductivity type body 14a and the low-density second conductivity type drain region 12a may be etched using the mask 16, to create the trench 18. For example, the low-density second conductivity type drain region 12a may be exposed by etching the first conductivity type body 14a by reactive ion etching (RIE) using the mask 16. The RIE may also etch the exposed low-density second conductivity type drain region 12a, without exposing the high-density second conductivity type drain region 10. As shown in example FIG. 2D, the gate oxide layer 20 may be formed over sidewalls and a lower part of the trench 18 through a thermal oxidation process.

As shown in example FIG. 2E, a polysilicon 22 may be vapor-deposited, for example by the CVD, over the surface of the semiconductor substrate, including the mask 16 and the gate oxide layer 20. For example, the polysilicon 22 may be vapor-deposited over the surface of the semiconductor substrate so as to be fully embedded in the trench 18. At the same time, the polysilicon 22 may be vapor-deposited also at the upper part of the mask 16. In the CVD method, a thin film is grown evenly over a surface. Therefore, for example, when the polysilicon 22 is formed thicker than a half of width of the trench 18, the polysilicon 22 fully fills the trench 18 and then grows upward evenly through the whole surface of the substrate.

Next, as shown in example FIG. 2F, the polysilicon 22 may be removed by etching, for example, by blanket etching until the mask 16 is exposed. The polysilicon 22 may be uniformly etched throughout the surface and accordingly, the mask 16 is gradually exposed. The polysilicon 22 may have high etching selectivity in comparison with the mask 16. The etching may be continued even after the mask 16 is exposed. In this case, the polysilicon 22 only in the trench 18 can be etched little by little, thereby achieving a desired thickness of the polysilicon 22.

Next, only the mask 16 may be selectively removed as shown in example FIG. 2G. As a result, the gate 22a in which the polysilicon 22 protrudes over the surface of the body 14a is formed. According to embodiments described above, dopant ion implantation for the first conductivity type in both gate 22a and the body 14a may be performed in the following manner. The polysilicon 22 may be vapor-deposited while being doped with dopant ions of the first conductivity type, as shown in example FIG. 2E. Otherwise, the polysilicon 22 may be etched and then implanted with the dopant ions of the first conductivity type, the same type as the body 14a as shown in example FIG. 2F. Then, the mask 16 may be removed as shown in example FIG. 2G. If the body 14a has the P-type conduction, the polysilicon 22 may be doped with P-type dopants.

Afterward, referring to example FIG. 1, the first photosensitive film mask 24 exposes the source region 28. The gate 22a may be formed over the whole surface of the body 14a. Using the first photosensitive film mask 24, high-density second conductivity type ions are implanted vertically or diagonally in the protruding portion of the gate 22, thereby forming the barrier layer 30. Additionally, high-density second conductivity type ions may be implanted in the surface of the body 14a, thereby forming the source region 28. It can be appreciated that the ions of the same density and the same conductivity type, which may be the second conductivity type, may be implanted when forming the source region 28 and the barrier layer 30. When forming the barrier layer 30, the second conductivity type ions may be implanted even in lateral sides of the protruding portion of the gate 22a, by using a tilt ion implantation method.

After the source region 28 and the barrier layer 30 are thus generated, the first photosensitive film mask 24 may be removed and a second photosensitive film mask may be formed. Therefore, the high-density first conductivity type body 26 may be formed using the second photosensitive film mask. The high-density first conductivity type body 26 may be formed prior to the barrier layer 30 and the source region 28.

Afterwards, a dielectric layer may be vapor-deposited over the surface of the semiconductor substrate including the barrier layer 30 and the source region 28 of the gate 22a. Then, contact holes for the gate and the source may be formed in the dielectric layer. By embedding metal such as tungsten in the hole, a gate contact and a source contact may be formed. A source contact, which may be self aligned, can be achieved using a sidewall formed over the gate electrode and the protruding portion of the gate 22a, using a CMOS process.

If the trench transistor according to embodiments is an n-channel metal-oxide semiconductor field-effect transistor (NMOSFET), high-density P-type dopants may be applied to the polysilicon to form the gate 22a. High-density N-type dopants may be implanted to simultaneously form the source region 28 and the barrier layer 30. Thus, when the gate 22a adjoining the N+ source region 28 is highly doped with the high-density N-type dopants, the barrier layer 30 may be formed between the P-type gate 22a and the N+ source region 28. This increases an interval between the P-type gate 22a and the N+ source region 28. As a result, overlap capacitance between the gate and the source is reduced. Since the gate-source overlap capacitance is achieved by the self alignment, variation in the overlap capacitance can also be reduced.

Example FIG. 3 is an energy band diagram showing a state where the body 14a and the gate 22a have different conductivity types from each other. Example FIG. 4 is an energy band diagram showing a state where the body 14a and the gate 22a have the same conductivity type. Ec refers to an energy level of a conduction band, and Ev refers to an energy level of a valence band.

Referring to the energy band diagram of example FIG. 3, wherein the P-type body and the N+ gate are used in an N-type trench MOS transistor, Fermi levels on both sides with respect to the gate oxide layer 40 are even, which means that external power is not applied. In such an even state wherein power is not applied, Fermi energy levels EF of the P-type body and the N+ gate, with different work functions, need to correspond to each other. Therefore, a certain depletion area is generated on a surface of the P-type body while a magnetic field is generated at the gate oxide layer 40. The depletion area forms due to the work function difference between the P-type body and the N+ gate. The depletion area facilitates generation of channels in the transistor. In other words, although a low gate voltage may be applied in the case where the depletion area is not formed in the even state, channels can be formed with ease.

Referring to example FIG. 4, however, because the dopants of the body 14a and the gate 22a are both the P-type, a depletion area is not generated without application of external power. When a voltage is applied to the gate 22a with respect to the silicon substrate, a depletion area is formed first. When the voltage increases, channel inversion is achieved. Therefore, in the case of example FIG. 4, a higher voltage is required to be applied to the gate 22a than in the case of example FIG. 3, for generation of the channels.

In other words, the gate oxide layer 20 needs to be thinned in order to obtain a threshold voltage value of example FIG. 3 with the transistor shown in example FIG. 4. When the gate oxide layer 20 is thin enough, electric charges are increased in accordance with an increase of the gate voltage, and accordingly transconductance (Gm=dID/dVG) of the transistor is increased. This means an improvement of the amplifying function of the transistor. Therefore, the transistor according to embodiments may be appropriate for an analog amplifier.

According to a manufacturing method for the trench transistor in accordance with the embodiments, a plurality of the P-type or N-type MOSFETs can be formed over a single semiconductor substrate. Also, over a single semiconductor substrate, at least one N-type MOSFET and P-type MOSFET can be formed simultaneously.

As apparent from the above description, the trench transistor and a manufacturing method thereof according to embodiments have several advantages as follows. Gate-source overlap capacitance may be reduced, thereby saving power consumed for driving the gate. Since the overlap between the gate and the source is achieved through the self alignment method, variation of the gate-source capacitance can be reduced. Consequently, stability of the gate capacitance is enhanced. By forming the gate electrode polysilicon to be higher than a surface of a body (i.e., to protrude from the body), the surface area of the device can be reduced, thereby guaranteeing the process margin. According to embodiments, the polysilicon doped with the P-type dopants may be used for forming an NMOSFET. Therefore, when forming a transistor with a relatively high threshold voltage, that is about 1˜1.5V, usually used in power MOS transistors, although a gate oxide layer having a relatively lower thickness than usual is used, increase of the gate-source capacitance can be prevented. Finally, when the relatively thin gate oxide layer is used, higher transconductance (Gm) can be obtained. Accordingly, the trench transistor may be used in an analogue amplifier.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a semiconductor substrate;
a trench formed within the semiconductor substrate;
a gate oxide layer formed over an inner wall of the trench;
a gate embedded in the trench including a protruding portion partly protruding over a surface of the semiconductor substrate, the gate doped with second conductivity type dopants around the protruding portion, and the gate doped with first conductivity type dopants on other portions excluding the protruding portion; and
a source region of a second conductivity type, formed over the surface of the semiconductor substrate at lateral sides of the trench.

2. The apparatus of claim 1, wherein the semiconductor substrate comprises a structure constituted by a first conductivity type body, a second conductivity type drain region having a first density, and a second conductivity type drain region having a second density.

3. The apparatus of claim 2, wherein the trench is formed over the first conductivity type body and the second conductivity type drain region having a second density.

4. The apparatus of claim 1, wherein the first conductivity type is a P type and the second conductivity type is an N type.

5. The apparatus of claim 1, wherein, in the gate, the protruding portion and lateral sides of the protruding portion are doped with second conductivity type dopants.

6. The apparatus of claim 2, wherein said first density is greater than said second density.

7. A method comprising:
preparing a semiconductor substrate;
forming a trench in the semiconductor substrate;
forming a gate oxide layer over an inner wall of the trench;
forming a gate having a first conductivity type by embedding polysilicon in the trench, the gate including a protruding portion protruding over a surface of the semiconductor substrate;
forming a barrier layer by implanting second conductivity type ions in the protruding portion; and
forming a second conductivity type source region over the surface of the semiconductor substrate.

8. The method of claim 7, wherein said preparing a semiconductor substrate comprises preparing the semiconductor substrate by ion implantation or epitaxy to include a first conductivity type body, a second conductivity type drain region having a first density, and a second conductivity type drain region having a second density.

9. The method of claim 8, wherein said forming the trench comprises:
vapor-depositing a silicon oxide layer over an upper part of the first conductivity type body by CVD;
forming a mask by patterning the silicon oxide layer which exposes a region for forming the trench while covering the other regions; and
etching the first conductivity type body and the second conductivity type drain region having a second density using the mask.

10. The method of claim 9, wherein the etching of the first conductivity type body and the second-density second conductivity type drain region comprises:
exposing the second-density second conductivity type drain region by etching the first conductivity type body by reactive ion etching (RIE) using the mask; and
performing RIE with respect to the exposed second-density second conductivity type drain region so that the first-density second conductivity type drain region is not exposed.

11. The method of claim 9, wherein said forming of the first conductivity type gate comprises:
vapor-depositing polysilicon over the surface of the semiconductor substrate while doping the polysilicon with the first conductivity type dopant ions, so that the polysilicon is fully embedded in the trench and formed over an upper part of the mask;
blanket etching the polysilicon until the mask is exposed; and
selectively removing the mask, thereby forming the gate in which the polysilicon is protruding over the surface of the body.

12. The method of claim 9, wherein said forming of the first conductivity type gate comprises:
vapor-depositing polysilicon over the surface of the semiconductor substrate, so that the polysilicon is fully embedded in the trench and formed over an upper part of the mask;
blanket etching the polysilicon until the mask is exposed;
implanting first conductivity type dopant ions in the blanket-etched polysilicon; and
selectively removing the mask, thereby forming the gate in which the polysilicon is protruding over the surface of the body.

13. The method of claim 7, wherein, in said forming of the gate oxide layer, the gate oxide layer is formed over sidewalls and a lower part of the trench through thermal oxidation.

14. The method of claim 8, wherein, in said forming of the barrier layer by implanting second conductivity type ions in the protruding portion, second conductivity type ions are implanted vertically to have a first density in the protruding portion, thereby forming the barrier layer at the protruding portion and lateral sides of the protruding portion.

15. The method of claim 12, wherein the polysilicon has high etching selectivity in preparation for the mask.

16. The method of claim 7, wherein the barrier layer and the source region are simultaneously formed by implanting the second conductivity type ions.

17. The method of claim 14, wherein, when forming the barrier layer by implanting the second conductivity type ions in the protruding portion, the source region is formed by implanting the second conductivity type ions in the first conductivity type body simultaneously.

18. The method of claim 7, wherein the first conductivity type is a P type and the second conductivity type is an N-type.

19. The method of claim 8, wherein said first density is greater than said second density.

20. The method of claim 8, wherein, in said forming of the barrier layer by implanting second conductivity type ions in the protruding portion, second conductivity type ions are implanted diagonally to have a first density in the protruding portion, thereby forming the barrier layer at the protruding portion and lateral sides of the protruding portion.
